(19) United States
(12) Patent Application Publication
(10) Pub. No.: US 2026/0372084 A1
(43) Pub. Date: Nov. 19, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Young Do Kweon, Chandler, AZ (US); Tadashi Takano, Irvine, CA (US)

(73) Assignee: Amkor Technology Singapore Holding Pte. Ltd., Singapore (SG)

(21) Appl. No.: 19/211,796

(22) Filed: May 19, 2025

(51) Int. Cl. H10W 40/25; H10W 70/60; H10W 72/00; H10W 72/30; H10W 74/15; H10W 90/00

(52) U.S. Cl. CPC H10W 40/25; H10W 70/60; H10W 90/00; H10W 72/07354; H10W 72/347; H10W 72/877; H10W 74/15; H10W 90/724; H10W 90/734; H10W 90/736

(57) ABSTRACT

In one example, an electronic device comprises a substrate comprising a dielectric structure and a conductive structure, a first electronic component over a first side of the substrate, wherein the first electronic component comprises a first side, a second side opposite the first side, a lateral side, and a corner at the lateral side, and wherein the corner comprises a vertical side and a horizontal side, a lid over the first side of the substrate and over the first electronic component, and a thermal interface material between the first side of the first electronic component and the lid. The thermal interface material covers the first side of the first electronic component and extends into the corner and covers the vertical side of the corner and the horizontal side of the corner. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2H show cross-sectional views of an example method for manufacturing an example electronic device.

FIGS. 3A to 3B show a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features. The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical or electrical coupling.

### DESCRIPTION

In one example, an electronic device comprises a substrate comprising a dielectric structure and a conductive structure, a first electronic component over a first side of the substrate, wherein the first electronic component comprises a first side, a second side opposite the first side, a lateral side, and a corner at the lateral side, and wherein the corner comprises a vertical side and a horizontal side, a lid over the first side of the substrate and over the first electronic component, and a thermal interface material between the first side of the first electronic component and the lid. The thermal interface material covers the first side of the first electronic component and extends into the corner and covers the vertical side of the corner and the horizontal side of the corner.

In another example, a method of manufacturing an electronic device comprises providing a wafer comprising a first side and a second side opposite the first side, in a first cutting operation, providing a first cut at a first location on the first side of the wafer, wherein the first cut partially extends from the first side to the second side, providing a metallization layer on the first side of the wafer, wherein the metallization layer extends into the first cut, and in a second cutting operation, cutting through the wafer and through the metallization layer at the first cut to provide a first electronic component having a corner at a lateral side the first electronic component. The corner of the first electronic component comprises a vertical side and a horizontal side, and the metallization layer covers the vertical side of the corner and the horizontal side of the corner.

In yet another example, an electronic device comprises an electronic component body comprising comprises a first side, a second side opposite the first side, a lateral side, and a corner at the lateral side, and wherein the corner comprises a vertical side and a horizontal side, a metallization layer on the first side of the electronic component body and extending into the corner of the electronic component body, and an external interconnect on the second side of the electronic component body. The metallization layer covers the vertical side of the electronic component body and the horizontal side of the electronic component body.

Other examples are included in the present disclosure. Such examples may be found in the figures, in the claims, or in the description of the present disclosure.

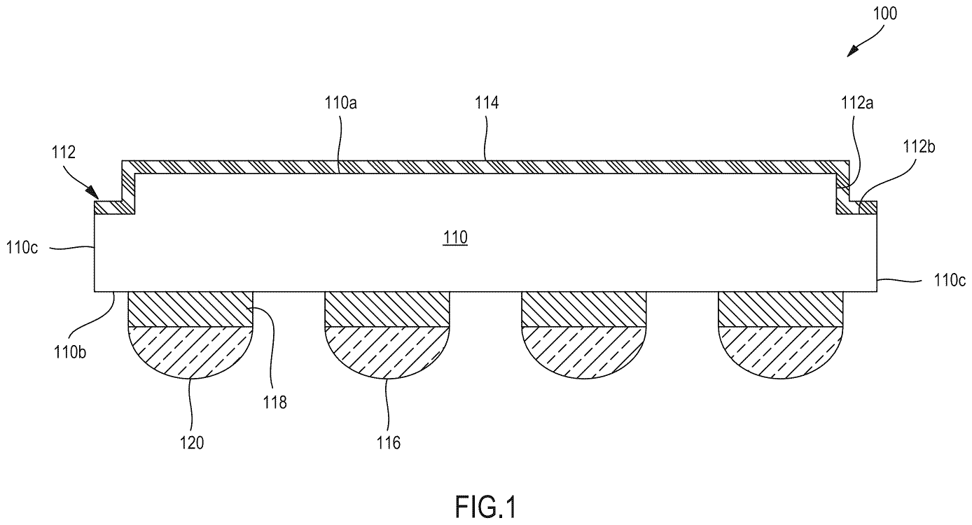

FIG. 1 shows a cross-sectional view of an example electronic device 100. In the example shown in FIG. 1, electronic device 100 can comprise electronic component 110 having a backside 110a and a frontside 110b opposite to the backside 110a. In some examples, frontside 110b can be an active side of electronic component 110. In some examples, electronic component 110 can be referred to as a body or an electronic component body. In some examples, backside 110a can comprise a top side of electronic component 110, and frontside 110b can comprise a bottom side of electronic component 110, although the scope of the disclosed subject matter is not limited in this respect. Electronic component 110 can also comprise lateral sides 110c between backside 110a and frontside 110b. In some examples, electronic component 110 can have one or more corners 112 at the lateral sides 110c of electronic component 110. Corners 112 can also be referred to as a notch, and edge, a ledge, or a metallized die edge. In some examples, corners 112 can run the length of one or more edges of electronic component 110, for example along or around the perimeter of electronic component 110. Corners 112 can be located at backside 110a of electronic component 110 and can comprise a vertical side 112a and a lateral side 112b. In one or more examples, backside 110a can be covered by layer 114 which can comprise a metal. In some examples, layer 114 can be referred to as backside metallization (BSM) or a metallization layer. In some examples, electronic device 100 can comprise a semiconductor device and can include one or more active circuits. In some examples, electronic device 100 can be referred to as a chip or a die, although the scope of the disclosed subject matter is not limited in this respect.

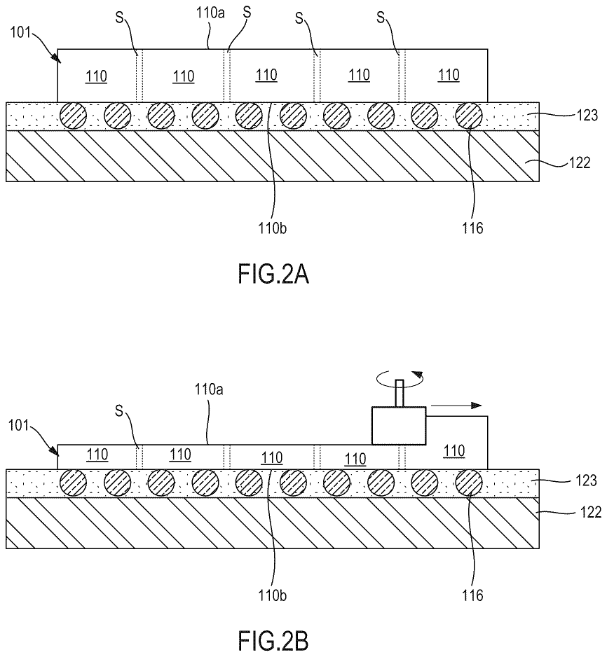

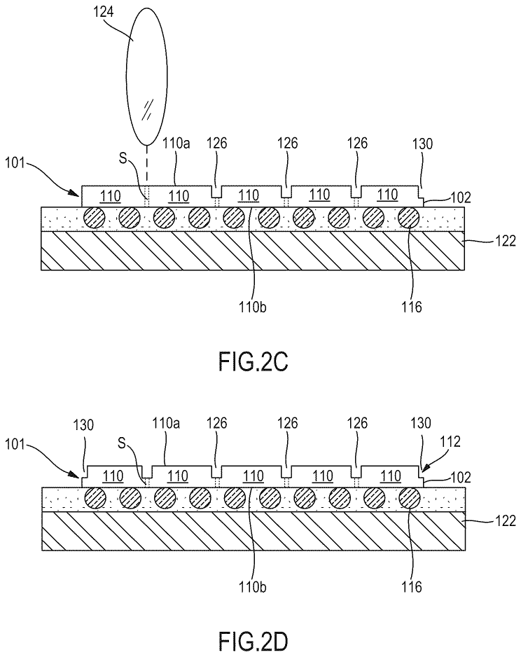

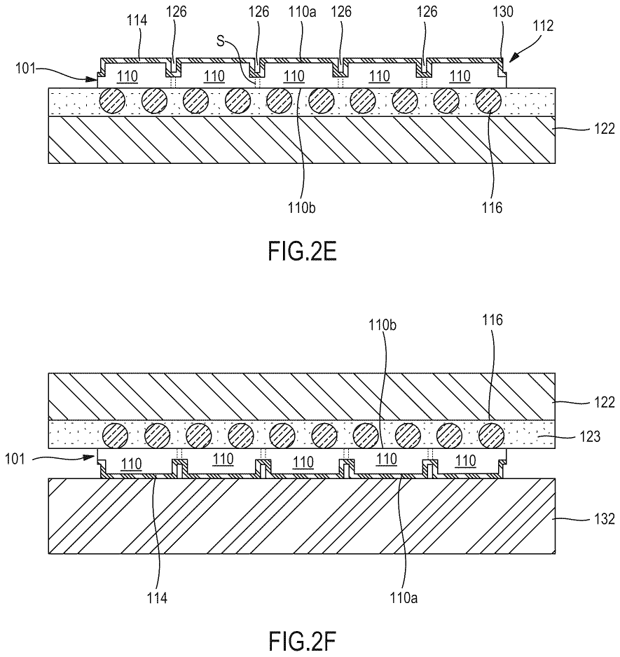

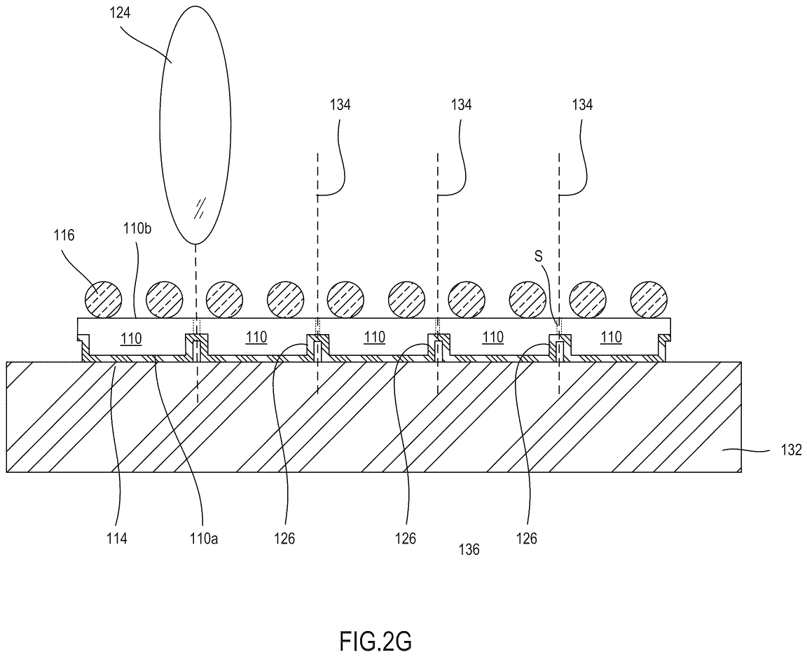

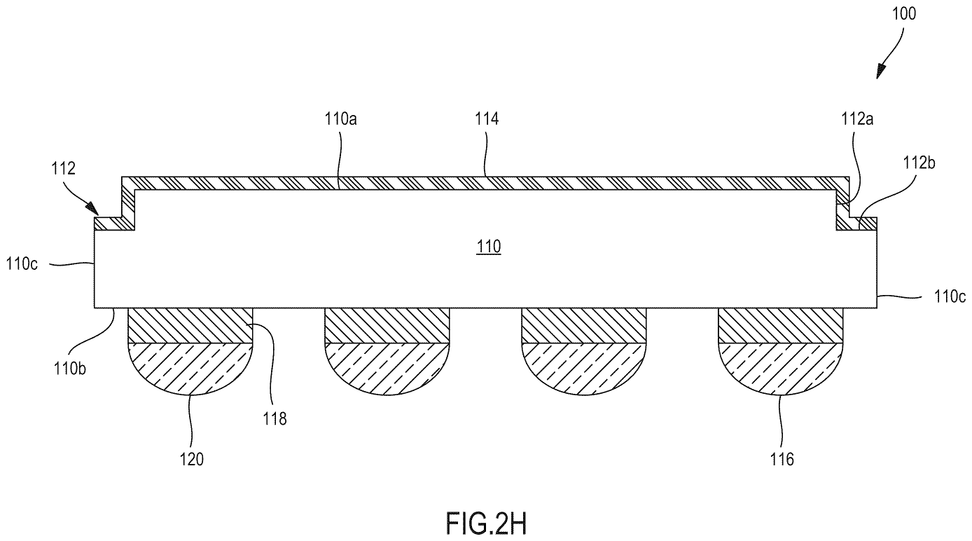

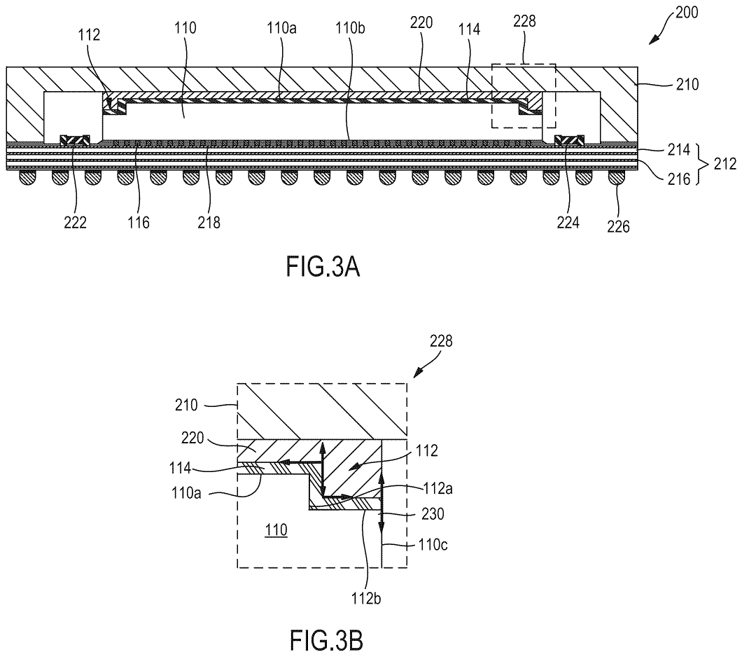

As shown in FIG. 1, layer 114 can cover backside 110a of electronic component 110 and can extend into corners 112. In some examples, layer 114 can cover vertical side 112a or lateral side 112b of corners 112. In some examples, layer 114 can extend to lateral sides 110c of electronic component 110. One or more external interconnects 116 can be located at frontside 110b of electronic component 110. External interconnects 116 can comprise contacts 118, or electrodes, and interconnect tips 120. In some examples, interconnect tips 120 can comprise a low melting point material, for example Sn, Ag, Pb, Sn—Pb, Sn37—Pb, Sn95—Pb, Sn—Pb—Ag, Sn—Cu, Sn—Ag, Sn—Au, Sn—Bi, Sn—Ag—Cu, or equivalents. In some examples, electronic device 100 can be part of a package with layer 114 provided in contact with another structure, for example to facilitate the transfer of heat out of electronic component 110 and into the other structure via layer 114, although the scope of the disclosed subject matter is not limited in this respect. An example of such a package is shown in FIG. 3A. An example process of manufacturing electronic device 100 is discussed with respect to FIGS. 2A to 2H below.

FIGS. 2A to 2H show cross-sectional views of an example method for manufacturing an example electronic device, such as electronic device 100 in FIG. 1. FIG. 2A shows a cross-sectional view of electronic device 100 at an early stage of manufacture. In the example shown in FIG. 2A, a wafer 101 can be provided on carrier 122. Wafer 101 can include a plurality of electronic components 110. Electronic components 110 can be arranged in rows and columns across wafer 101 with saw streets S located between adjacent electronic components 110. As described in further detail below, individual electronic components 110 can be singulated from wafer 101 at a later stage of manufacture.

Wafer 101 can be coupled to carrier 122 with frontside 110b of electronic components 110 facing carrier 122, and backside 110a of electronic components 110 facing away from carrier 122. In some examples, carrier 122 can comprise a material or temporary bonding layer or film 123 that can accommodate and cover external interconnects 116 of electronic component 110. Bonding film 123 can be adhered to frontside 110b of electronic components 110 and external interconnects 116. Temporary bonding film 123 can comprise or be referred as to temporary adhesive, temporary tape, temporary bonding film, or peelable adhesive. The bonding film 123 can lose its adhesive force by heat, ultra-violet light, a laser beam, or chemical solution or can be separated from electronic components 110 and external interconnects 116 by an external force. In some examples, bonding film 123 can have a thickness sufficient to enclose external interconnects 116.

FIG. 2B shows a cross-sectional view of electronic device 100 at a later stage of manufacture. In the example shown in FIG. 2B, the upper side or backside 110a of electronic component 110 can be ground down to a desired thickness in a backgrinding (BG) or wafer thinning process. In some examples, the resulting thickness of electronic components 110 after backgrinding can be selected based on a desired thickness of the package into which the electronic component 110 will be ultimately disposed. In accordance with examples, wafer 101 can be subjected to backgrinding or wafer thinning to thin electronic components 110.

FIG. 2C shows a cross-sectional view of electronic device 100 at a later stage of manufacture. In the example shown in FIG. 2C, one or more cuts 126 can be provided in backside 110a of electronic components 110, for example using a cutting device 124 (e.g., blade saw or laser). The cuts 126 can be located in (e.g., vertically aligned with) saw streets S. For example, cuts 126 can be made between adjacent electronic components 110. In some examples, one or more cuts 130 can be made in the backside 110a of electronic components 110 at the lateral sides 102 of wafer 101. For example, cuts 130 can be at the lateral sides of the outermost electronic components 110 of wafer 101. In some examples, the cuts 126 can be located in saw streets S using infrared (IR) alignment. In some examples, the cuts 126 can comprise partial cuts in backside 110a of electronic component 110 that do not completely penetrate through wafer 101. For example, a portion of wafer 101 can remain between the floor of the cut 126 and frontside 110 b. In some examples, cuts 126 can extend between approximately 15% and approximately 75% of the thickness of wafer 101. In some examples, the depth of cuts 126 can be between approximately 25% and approximately 60% of the thickness of wafer 101. In some examples, the depth of cuts 126 can be between approximately 45% and approximately 55% of the thickness of wafer 101. In some examples, the depth of cuts 126 can be approximately 50% of the thickness of wafer 101.

As shown in FIG. 2D, the cuts 126 and 130 in the upper side of wafer 101 will correspond to the corners 112 of individual electronic devices 110 after singulation. In some examples, cuts 126 between adjacent electronic component 110 can have a width that is approximately twice the width of the resulting corners 112 after singulating, or dicing, wafer 101 into individual electronic components 110. In some examples, the width of cuts 130 at the lateral sides 102 of wafer 101 (e.g., the cuts at the lateral sides of the outermost electronic components 110 of wafer 101) can be smaller than the width of the interior cuts 126. For example, the width of cuts 130 can be the width of horizontal side 112b as shown in FIG. 1, and the width of cuts 126 can be approximately twice the width of horizontal side 112b. In some examples, the width of cuts 126 can be selected to account for the kerf resulting from the singulating process so that the width of cuts 126 is approximately twice the width of horizontal side 112b plus the kerf width, although the scope of the disclosed subject matter is not limited in this respect.

FIG. 2E shows a cross-sectional view of electronic device 100 at a later stage of manufacture. In the example shown in FIG. 2E, layer 114 can be deposited on backside 110a of electronic components 110. Layer 114 can be provided to cover backside 110a of electronic components 110. For example, layer 114 can contact backside 110a and can extend along the sidewalls and floors of cuts 126 and 130. In some examples, layer 114 can comprise or be referred to as a backside metallization (BSM) plating layer, a conductive layer, or a conductive film. For example, layer 114 can be provided by electrolytic plating, electroless plating, sputtering, physical vapor deposition (PVD), vacuum metallization, transfer metallization, or metallizing paint, or a combination thereof. In some examples, layer 114 can be made of gold (Au) or silver (Ag). In some examples, layer 114 can comprise a multi-layer metal stack. For example, layer 114 can comprise an adhesion layer (e.g., Ti or TiW) applied on backside 110a, a barrier layer (e.g., Ni or NiV) applied on the adhesion layer, and a wetting layer (e.g., Au or Ag) applied on barrier layer. In some examples, the thickness of layer 114 can range from approximately 0.3 μm to approximately 10 μm.

Layer 114 can extend into cuts 126 and 130 such that vertical side 112a and horizontal side 112b of corners 112 as shown in FIG. 1 are covered by layer 114. As a result of the backside metallization process, electronic components 110 can have a metallized die edge or corner 112 at the lateral sides 110c (FIG. 1) of the electronic component 110, which can enhance metal thermal interface material (TIM) wetting at corner 112 of electronic components 110. For example, individual electronic components 110 can be part of a package as shown in and described with respect to FIG. 3A below.

FIG. 2F shows a cross-sectional view of electronic device 100 at a later stage of manufacture. In the example shown in FIG. 2F, carrier 122 and wafer 101 including electronic components 101 with layer 114 formed thereon can be inverted and placed on another carrier 132 for further processing. Carrier 122 and bonding film 123 can be removed or released from frontside 110b of electronic components 110 and from external interconnects 116 prior to further processing as shown in FIG. 2G.

FIG. 2G shows a cross-sectional view of electronic device 100 at a later stage of manufacture. In the example shown in FIG. 2G, after carrier 122 and bonding film 123 have been removed, electronic components 110 can be singulated into individual components by cutting or sawing at cut lines 134 with cutting device 124 (e.g., with a saw blade or laser). Cut lines 134 can correspond to saw street S and the locations of cuts 126, for example from frontside 110b of electronic component 110. The sawing can completely cut through electronic component 110 and through layer 114. After cutting, individual electronic components 110 can be removed or picked up from carrier 132. In some examples, each of cuts 126 and 130 can correspond to a metallized corner 112 of electronic component 110 as shown in FIG. 2H.

FIG. 2H shows a cross-sectional view of electronic device 100 at a later stage of manufacture. In the example shown in FIG. 2H, an individual electronic component 110 can be provided as a result of the singulation process. Individual electronic components 110 can have layer 114 covering backside side 110a of electronic component 110. Layer 114 also covers vertical side 112a and horizontal side 112b of corners 112 of electronic component 110. In some examples, the saw 124 or cutting tool used for the singulation process can be used to remove some of the material of layer 114 over horizontal side 112b while still leaving enough remaining material of layer 114 covering vertical side 112a and horizontal side 112b. Individual electronic components 110 having metallized corners 112 can be provided in a package as shown in FIG. 3A.

FIG. 3A shows a cross-sectional view of an example of electronic device 200. In the example shown in FIG. 3A, electronic device 200 can comprise electronic component 110 coupled with substrate 212 and having lid 210 over electronic component 110 and over substrate 212. Lid 210 can comprise a metal in some examples. Substrate 212 can comprise dielectric structure 214 and conductive structure 216. In some examples, external interconnects 116 of electronic component 110 can be coupled with conductive structure 216 of substrate 212. External interconnects 116 can be covered by underfill 218 between substrate 212 and frontside 110b of electronic component 110. In some examples, electronic device 200 can be referred to as a package, although the scope of the disclosed subject matter is not limited in this respect.

Substrate 212 can comprise a core or can be coreless. In some examples, substrate 212 can comprise or be referred to as a rigid printed circuit board, a flexible printed circuit board, a rigid laminate substrate, a flexible laminated substrate, a redistribution layer (RDL) substrate, a build-up substate, a ceramic substrate, a glass substrate, or a silicon substrate. In some examples, an area, or footprint, of substate 212 can varying according to the area or number of electronic components including but not limited to electronic component 110, electronic component 222, and electronic component 224 mounted to substrate 212.

In some examples, substrate 212 can be an RDL, or build-up substrate. RDL substrates can comprise one or more conductive redistribution layers and one or more dielectric layers and (a) can be formed layer by layer over an electronic device to which the RDL substrate is coupled, or (b) can be formed layer by layer over a carrier which can be removed, entirely or at least partially, after formation of the RDL substrate. For example, the RDL substate can be formed layer by layer over a carrier, an electronic device can then be connected to the RDL substrate, and the carrier can be removed with the electronic device connected to the RDL substrate. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process, for example an electroplating process or an electroless plating process. The conductive patterns can comprise a conductive material, for example copper or other plateable metal. The locations of the conductive patterns can be made using a photo-patterning process, for example a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials, for example, PI, BCB, or PBO. Such dielectric materials can be spun-on or otherwise coated in liquid form rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples, the dielectric materials of the RDL substrates can comprise one or more inorganic dielectric layers. Some examples of one or more inorganic dielectric layers can comprise silicon nitride (Si3N4), silicon oxide (SiO2), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure such as, for example, a dielectric material comprising BT or FR4 and these types of RDL substrates can comprise or be referred to as a coreless substrate. Substrate 212, as disclosed herein, can comprise an RDL substrate and can be formed on a carrier.

In some examples, substrate 212 can be a pre-formed, or laminate, substrate. The pre-formed/laminate substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure comprising dielectric material such as, for example, BT or FR4, and dielectric and conductive layers can be provided over the permanent core structure. In other examples, the pre-formed substrate can be a coreless substrate that omits the permanent core structure. The pre-formed substrate can be referred to as a printed circuit board (PCB) or a laminate substrate. Such pre-formed substrate can be formed through a semi-additive or modified-semi-additive process.

In some examples, thermal interface material (TIM) 220 can be on a top side of electronic component 110 and can be between electronic component 110 and lid 210. TIM 220 can contact metallization layer 114 on backside 110a such that bonding strength and thermal conduction between TIM 220 and electronic component 110 can increased. For example, metallization layer 114 can enhance bonding of TIM 220 to electronic component 110 and can enhance heat transfer from electronic component 110 to TIM 220. In some examples, metallization layer 114 can be considered part of electronic component 110 such that contact with a top side of electronic component 110 can mean contact with metallization layer 114 of electronic component 110. TIM 220 can extend into corners 112 of electronic component and can cover vertical side 112a and horizontal side 112b. In some examples, TIM 220 can comprise a metallic TIM. For example, TIM 220 can comprise metal or metal alloy materials such as gallium, gallium alloys such as alloys with indium, tin, or zinc, silver alloys, tin-silver, indium, and indium alloys. In examples where TIM 220 is a metal TIM, a preform alloy sheet can be inserted between lid 210 and metallization layer 114 to provide TIM 220. In some examples, TIM 220 can comprise a polymer TIM. The thermal conductivity of TIM 220 facilitates heat generated by electronic component 110 to be transferred to lid 210. TIM 220 can be applied to backside 110a of electronic component 110 by dispensing or printing. The thickness of TIM 220 can range from approximately 10 μm to approximately 300 μm.

In some examples, additional electronic components such as electronic component 222 and electronic component 224 can be coupled with substrate 212 and can be covered by lid 210. Substrate 212 can include one or more external substrate interconnects 226 on a side of substrate 212 opposite to electronic component. In some examples, the metallized corners 112 of electronic component 110 can operate to reduce tensile stress at backside 110a or backside of electronic component and at lateral sides 110c of electronic component 110. An enlargement 228 of electronic component 110 at the corner 112 is shown in FIG. 3B

FIG. 3B shows a cross-sectional view of an example of electronic device 200. In the example shown in FIG. 3B, enlargement 228 shows corner 112 of electronic component 110. TIM 220 can be disposed over backside 110a or backside of electronic component 110 and can extend into corner 112. TIM 220 can be between backside 110a of electronic component and lid 210. The metallized corner 112 of electronic component 110 having metallization layer 114 covering vertical side of 112a and horizontal side 112b of corner, for example as shown in FIG. 2H, can enhance wetting of TIM 220 at corners 112 of electronic component 110. As a result, a greater amount of heat can be transferred into lid 210 at corners 112 of electronic component 110 resulting in a reduction in thermal stress at corners 112. Such a configuration can also reduce the tensile stress forces between electronic component 110 and TIM 220 and between TIM 220 and lid 210. Because corners 112 have a larger surface area than the edges of electronic component 110 otherwise have without corners 112, the stress as represented by stress vectors 230 can be distributed over a larger area at or near the lateral sides 110c of electronic component 110 to result in a lower or reduced amount of stress per unit area. Providing a reduced stress at lateral sides 110c of electronic component due to metallized corners 112 can eliminate or reduce delamination of TIM 220 from electronic component 110, especially at lateral sides 110c and corners 112 of electronic component 110. Therefore, corners 112 of electronic component 110 can achieve a longer TIM bond line thickness (BLT) lifetime, and can reduce a TIM crack ratio at lateral sides 110c and corners 112 of electronic component 110. A greater amount of coverage of TIM 220 at corners 112 can be achieved, for example where TIM 220 comprises a metal TIM or for polymer TIM Flip Chip Ball Grid Array (FCLBGA) packages such as electronic device 200. It should be noted that these are merely examples of results that can be achieved by providing an electronic component 110 having a corner 112 covered by metallization layer 114, and the scope of the disclosed subject matter is not limited in these respects.

The present disclosure includes reference to certain examples. It will be understood by those skilled in the art, however, that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

1. An electronic device, comprising:
a substrate comprising a dielectric structure and a conductive structure;
a first electronic component over a first side of the substrate, wherein the first electronic component comprises a first side, a second side opposite the first side, a lateral side, and a corner at the lateral side, and wherein the corner comprises a vertical side and a horizontal side;
a lid over the first side of the substrate and over the first electronic component; and
a thermal interface material between the first side of the first electronic component and the lid;
wherein the thermal interface material covers the first side of the first electronic component and extends into the corner and covers the vertical side of the corner and the horizontal side of the corner.

2. The electronic device of claim 1, wherein:
the first electronic component has a metallization layer covering the first side of the first electronic component and covering the vertical side of the corner and the second side of the corner.

3. The electronic device of claim 2, wherein:
wherein the thermal interface material is between the metallization layer and the lid.

4. The electronic device of claim 1, wherein:
the lid comprises a metal.

5. The electronic device of claim 1, wherein:
a thickness of the thermal interface material at the corner of the first electronic component is greater than a thickness of the thermal interface material at a central portion of the first side of the first electronic component.

6. The electronic device of claim 1, comprising:
an underfill between the second side of the first electronic component at the substrate.

7. The electronic device of claim 6, wherein:
the first electronic component comprises an external interconnect coupled with the conductive structure; and
the underfill covers the external interconnect.

8. The electronic device of claim 1, comprising:
a second electronic component coupled with the substrate and covered by the lid.

9. The electronic device of claim 1, wherein:
a thickness of the first electronic component at the corner is less than a thickness of the first electronic component at a central portion of the first electronic component.

10. The electronic device of claim 1, wherein:
the thermal interface material extends to the lateral side of the first electronic component.

11. A method of manufacturing an electronic device, comprising:
providing a wafer comprising a first side and a second side opposite the first side;
in a first cutting operation, providing a first cut at a first location on the first side of the wafer, wherein the first cut partially extends from the first side to the second side;
providing a metallization layer on the first side of the wafer, wherein the metallization layer extends into the first cut; and
in a second cutting operation, cutting through the wafer and through the metallization layer at the first cut to provide a first electronic component having a corner at a lateral side the first electronic component;
wherein the corner of the first electronic component comprises a vertical side and a horizontal side; and
wherein the metallization layer covers the vertical side of the corner and the horizontal side of the corner.

12. The method of claim 11, wherein:
the wafer comprises the first electronic component and a second electronic component; and
the first cut is between the first electronic component and the second electronic component.

13. The method of claim 11, comprising:
a plurality of external interconnects coupled with the wafer.

14. The method of claim 13, wherein:
the wafer is provided on a first carrier prior to the first cutting operation; and
the plurality of external interconnects extends into the first carrier.

15. The method of claim 14, wherein the first carrier comprises a temporary film.

16. The method of claim 14, wherein:
the first carrier is removed after the first cutting operation;
the wafer is provided on a second carrier with the first side of the wafer facing the second carrier; and
the first electronic component is removed from the second carrier after the second cutting operation.

17. The method of claim 11, comprising:
in the first cutting operation, providing a second cut at lateral side of the wafer;
wherein a width of the first cut is greater than a width of the second cut.

18. The method of claim 17, wherein:
the first cut comprise a half cut; and
the second cut comprise a full cut.

19. An electronic device, comprising:
an electronic component body comprising comprises a first side, a second side opposite the first side, a lateral side, and a corner at the lateral side, and wherein the corner comprises a vertical side and a horizontal side;
a metallization layer on the first side of the electronic component body and extending into the corner of the electronic component body; and
an external interconnect on the second side of the electronic component body;
wherein the metallization layer covers the vertical side of the electronic component body and the horizontal side of the electronic component body.

20. The electronic device of claim 19, wherein:
a thickness of the electronic component body at a central portion of the first side is greater than a thickness of the electronic component body at the corner of the electronic component body.
